(19) United States
(12) Patent Application Publication
(10) Pub. No.: US 2014/0036451 A1
(43) Pub. Date: Feb. 6, 2014

(54) HEAT SINK ASSEMBLY

(71) Applicants: Glenn C. Simon, Auburn, CA (US); David R. Cowles, Granite Bay, CA (US); James D. Hensley, Rocklin, CA (US); Chadi Farid Theodossy, Rocklin, CA (US); David G. Rohrer, Auburn, CA (US); Teri F. Greenhoe, Rocklin, CA (US)

(72) Inventors: Glenn C. Simon, Auburn, CA (US); David R. Cowles, Granite Bay, CA (US); James D. Hensley, Rocklin, CA (US); Chadi Farid Theodossy, Rocklin, CA (US); David G. Rohrer, Auburn, CA (US); Teri F. Greenhoe, Rocklin, CA (US)

(21) Appl. No.: 13/563,393

(22) Filed: Jul. 31, 2012

(51) Int. Cl. H05K 7/20; H05K 13/00

(52) U.S. Cl. 361/720; 29/592.1

(57) ABSTRACT

A heat sink assembly includes a printed circuit board, a heat sink, and clamp, and at least two clamp retainers. The printed circuit board has at least two holes extending from a front surface to a back surface of the printed circuit board. The heat sink is mounted to the printed circuit board. The heat sink has a bottom side and a plurality of fins extending from a top side. The clamp is coupled to the printed circuit board. The clamp includes a beam extending across the heat sink and between adjacent fins, at least two legs extending through the at least two holes of the printed circuit board, and a foot extending from each of the at least two legs contacting the back surface of the printed circuit board. The at least two clamp retainers extend through the at least two holes adjacent to the at least two legs.

### BACKGROUND

Heat sinks are typically mounted to an outer surface of an integrated circuit package to facilitate the dissipation of heat from the integrated circuit contained within the package. Most heat sinks are thermally conductive and have a plurality of extruded fins to provide a large surface area, which allows heat to be more efficiently dissipated by natural or forced convection. Heat sinks are mounted to integrated circuit packages in a variety of ways. Many of the common methods of attachment use special tools to facilitate attachment without the heat sink becoming unstable or damaged.

Methods of attaching heat sinks to packages include common spring clamps, conventional clips which use a tool to attach the clip to the assembly, and adhesives.

### BRIEF DESCRIPTION OF THE DRAWINGS

FIG. 1 illustrates a top perspective view of one embodiment of an assembled heat sink assembly.

FIG. 2 illustrates a top perspective view of a disassembled heat sink assembly illustrated in FIG. 1 according to one embodiment.

FIGS. 3A and 3B illustrate side views of one embodiment of a clamp retainer.

FIGS. 4A and 4B illustrate exploded cross-sectional views of one embodiment of the heat sink assembly illustrated in FIG. 1.

FIG. 5 illustrates a top perspective view of one embodiment of an assembled heat sink assembly.

FIG. 6 illustrates a top perspective view of a disassembled heat sink assembly illustrated in FIG. 5 according to one embodiment.

FIG. 7 illustrates a side view of the heat sink assembly illustrated in FIG. 5.

FIG. 8 illustrates a top view of the heat sink assembly illustrated in FIG. 5.

FIG. 9 illustrates a block diagram of one embodiment of a method.

### DETAILED DESCRIPTION

In the following detailed description, reference is made to the accompanying drawings which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that features of the various embodiments described herein may be combined with each other, unless specifically noted otherwise.

Heat sinks are subjected to vibration during normal operation or transportation. Certain conventional clips are prone to slip relative to the heat sink and dislodge from attachment to the integrated circuit. This can seriously reduce the stability of a heat sink assembly and the efficiency of heat removal.

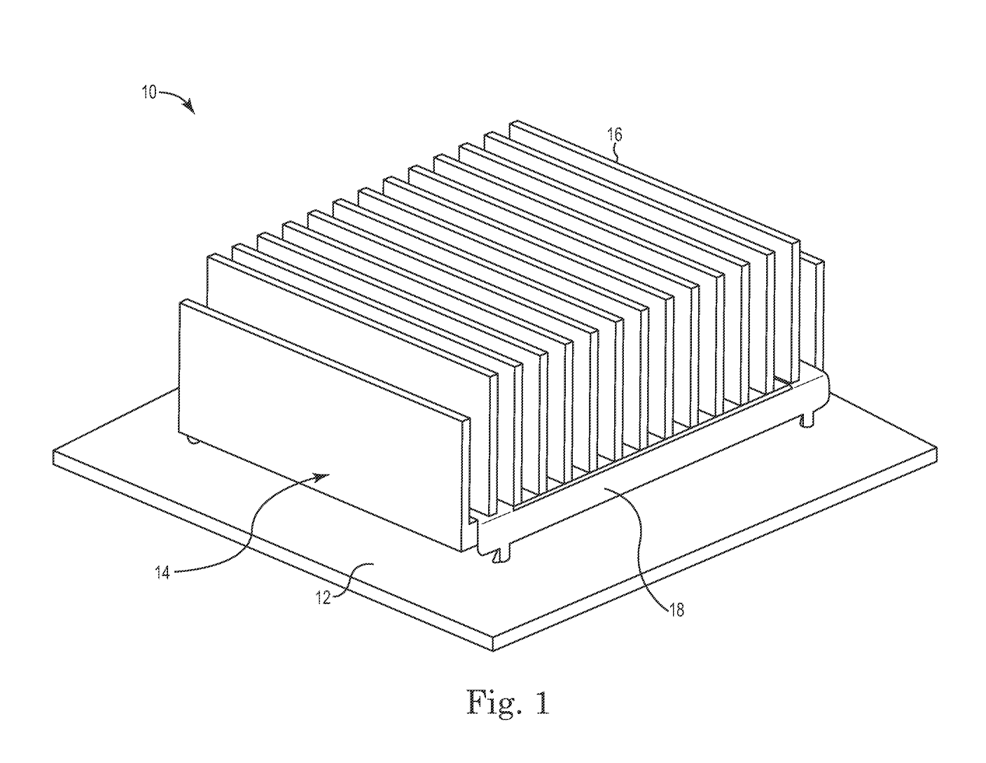

Embodiments provide heat sink assemblies which provide proper load pressure at the thermal connection surfaces and ground heat sinks for EMI compliance. FIG. 1 illustrates a top perspective view of a heat sink assembly 10 according to one embodiment. Heat sink assembly 10 includes a printed circuit board (PCB) 12, a heat sink 14 having a plurality of fins 16, and a clamp 18 coupling heat sink 14 to PCB 12. Clamp retainers 20 (not shown) are coupled to PCB 12 and clamp 18 as further discussed below.

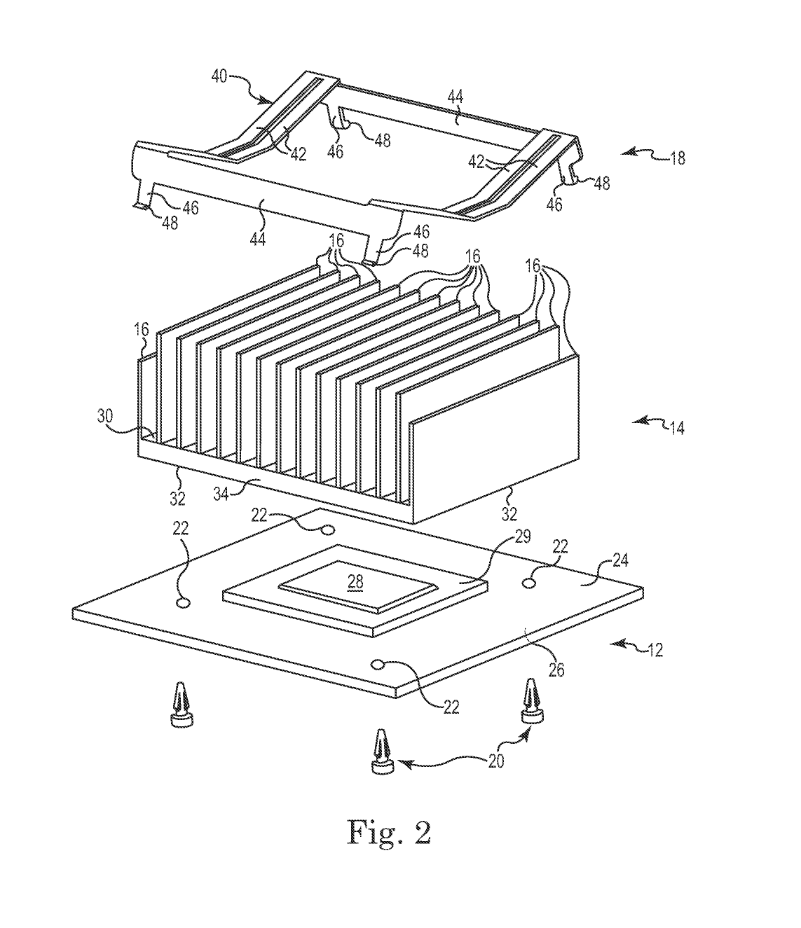

FIG. 2 illustrates a top perspective view of heat sink assembly 10 according to FIG. 1 in a disassembled state. A heat producing device 29 is mounted on front surface 24 of PCB 12. Heat producing device 29 is located centrally with respect to holes 22. Heat producing device 29 is an application specific integrated circuit (ASIC) or other electronic devices which generates heat and a heat spreader 28 is mounted unto heat producing device 29. Heat sink 14 is mounted onto the heat spreader 28 with a bottom surface 32 of heat sink 14 in contact with heat spreader 28. Heat sink 14 can be a simple aluminum extrusion and includes a plurality of extruded fins 16 extending in a parallel manner along from a top side 30. PCB 12 includes a series of holes 22 extending from a front surface 24 to a back surface 26 of PCB 12. Holes 22 are configured to be spaced along perimeter edge 34 of heat sink 14 and spaced to center heat sink 14 on heat producing device 29. Perimeter edge 34 of heat sink 14 is positioned adjacent to holes 22 of PCB 12 such that holes 22 are accessible from front surface 24 or back surface 26 when heat sink 14 is coupled to PCB 12.

In one embodiment, holes 22 are a simple cylindrical shape, although other shapes are acceptable as appropriate to receive clamp 18 and clamp retainer 20. Holes 22 are sized appropriately to receive clamp retainers 20. In one embodiment, holes 22 are drilled into PCB 12. At least two holes 22 are defined by PCB 12. In this embodiment, four holes 22 are illustrated. More or less holes 22 are appropriate as corresponding to quantity of legs 46 included on clamp 18, to allow use of multiple clamps 18, or for ease of manufacturing.

Clamp 18 secures heat sink 14 to heat producing device 29 on PCB 12. Clamp 18 is a stamped spring clamp. In one embodiment, clamp 18 is a single piece of metal plate which has been stamped into the desired form to act as a spring. Clamp 18 produces sufficient force to secure heat sink 14 to heat generating device 29 and PCB 12. Clamp 18 can be stamped from an aluminum or tin material, for example. Clamp 18 is formed from a stamped metal of 0.3 to 0.5 mm thick material.

Clamp 18 includes a body 40, at least two legs 46 extending from body 40, and at least two feet 48. Body 40 includes at least one beam 42 configured to extend between adjacent fins 16 to opposing perimeter edges 34 of heat sink 14. The width of beam 42 is appropriate to extend between two adjacent fins 16. With continued reference to FIG. 2, beams 42 in an unbiased state are bent in an arcuate form. In a biased or assembled state, beams 42 are substantially planar and parallel to top side 30 of heat sink 14, as illustrated in FIG. 1, and maintain a consistent load over dimensional tolerance variations.

In one embodiment, body 40 of clamp 18 includes edges 44 extending between and connecting multiple beams 42. In one embodiment, two parallel beams 42 are included on opposing ends of clamp 18 with edges 44 extending between. In one embodiment, edges 44 are perpendicular to beams 42. In one embodiment, clamp 18 includes multiple beams 42 which are distributed across the surface of heat sink 14 to provide an even distribution of applied loads when assembled to heat sink 14. Factors which contribute to determining the quantity, size and material characteristics of beams 42 include the load requirement of the thermal interface material of heat spreader 29 and the mass of heat sink 14, for example. Other factors can also be considered.

Clamp 18 has at least two legs 46 with each leg 46 terminating in a foot 48. Feet 48 are formed at an angle to legs 46. Feet 48 form hooks which protrude through holes 22 of PCB 12 and hold clamp 18 firmly in place using the spring force of the clamp 18 to bias feet 48 upward to contact bottom surface 26 of PCB 12 when assembled. In one embodiment, legs 46 extend from opposing corners of the clamp. In one embodiment, legs 46 are generally aligned with beams 42.

Clamp 18 can be installed manually, or with a tool to aid in compression and installation. Clamp 18 is biased with beam 42 between adjacent fins 16 of heat sink 14 to extend legs 46 and feet 48 through holes 22 of PCB 12. Pressure placed on beam 42 or legs 46 is released and feet 48 resiliently abut against back surface 26 of PCB 12. Once clamp 18 is in place, clamp retainers 20 are inserted into the same holes 22 that legs 46 occupy. Clamp retainer 20 occupies the space of hole 22 that leg 46 does not already occupy. In this manner, hole 22 is substantially filled and prevents dislocation of clamp 18. Clamp retainers 20 secure legs 46 and feet 48 in order that they do not become dislodged during a mechanical shock but are not under any load under normal conditions. In this manner, clamp 18 is configured to withstand a 30 G shock event.

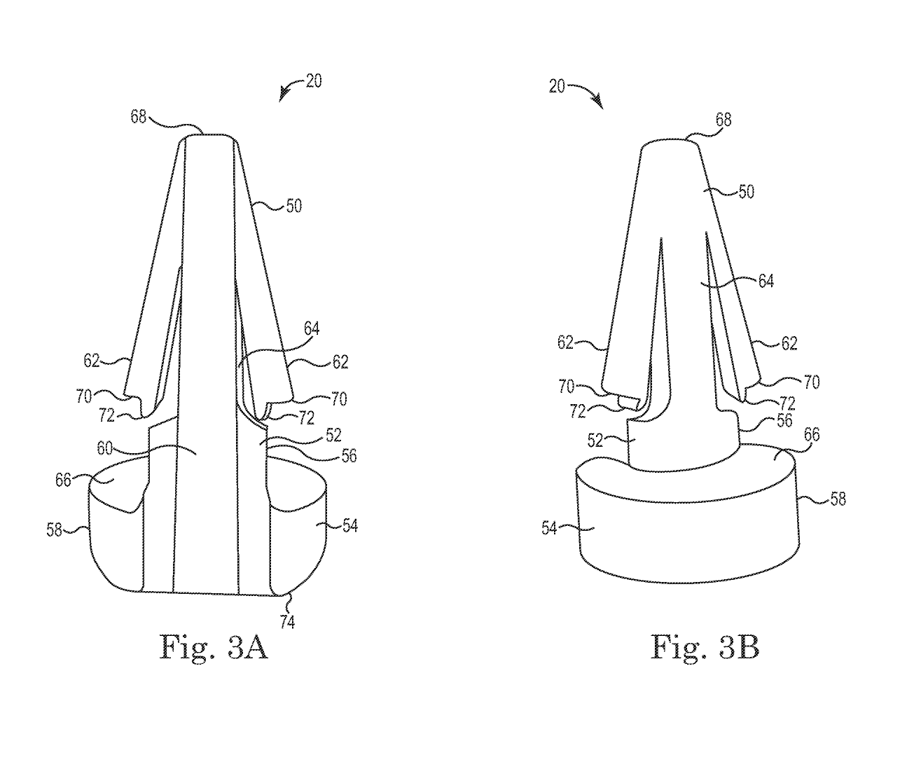

FIGS. 3A and 3B illustrate one embodiment of clamp retainer 20. Clamp retainer 20 includes a head 50, a bottom section 54, and a middle section 52 extending between head 50 and bottom section 54. Clamp retainer 20 includes a groove 60 extending from head 50 to bottom section 54. Groove 60 is shaped to accommodate leg 46 and foot 48. Clamp retainer 20 is insertable into hole 22 and can occupy hole 22 simultaneously with leg 46.

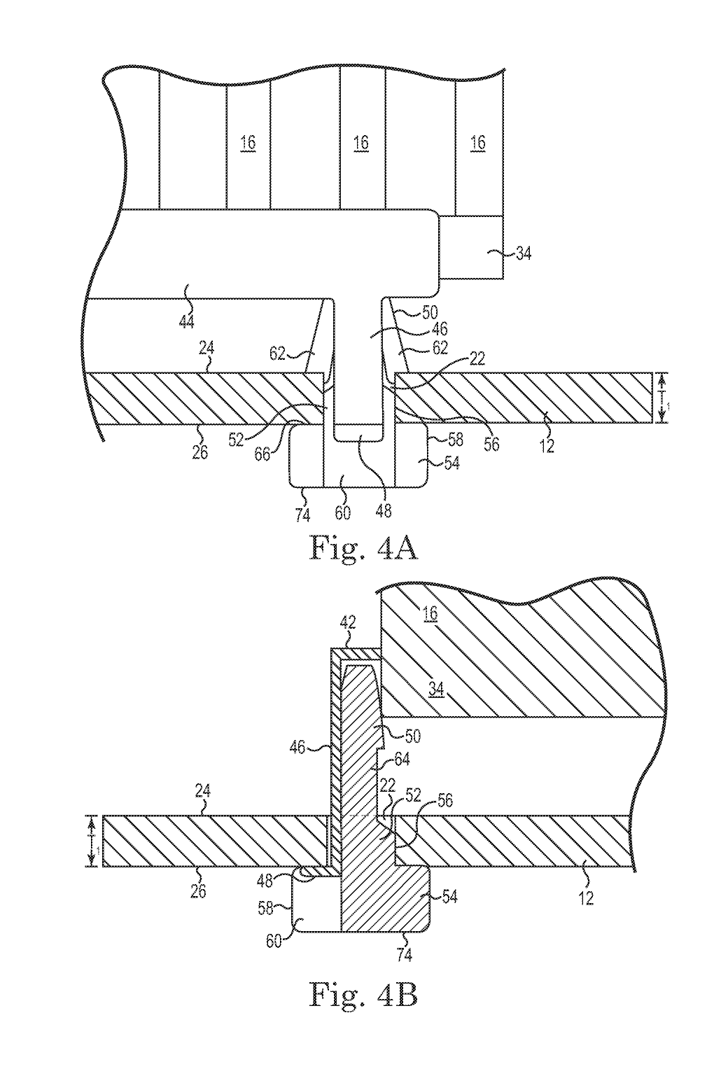

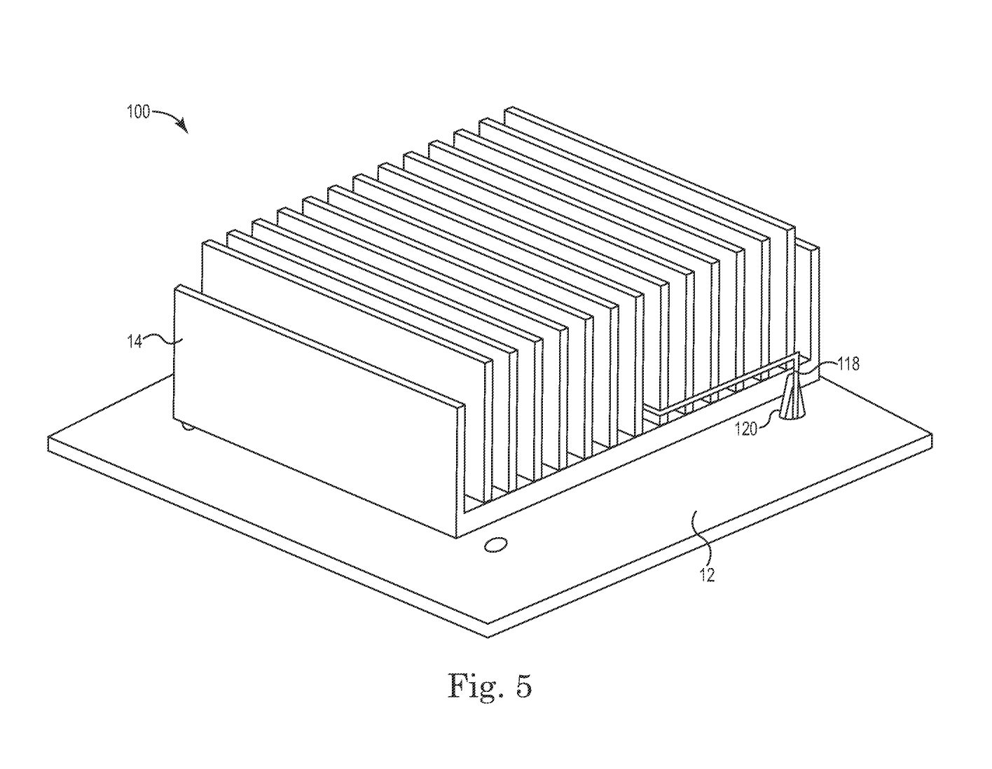

Middle section 52 has a first perimeter 56 configured to extend within hole 22 of PCB 12. Middle section 52 has a length which allows it to extend within the thickness T₁ of PCB 12, as illustrated in FIGS. 4A and 4B. With continued reference to FIGS. 3A and 3B, bottom section 54 has a second perimeter 58 which is larger than first perimeter 56 of middle section 52, thereby preventing bottom section 54 from entering hole 22. Bottom section 54 is configured to extend from middle section 52 and includes a contact surface 66 and a bottom surface 74 opposite contact surface 66.

Head 50 includes a main body 64 extending from a first end 68 to middle section 52. Head 50 includes tabs 62 joined to main body 64 at first end 68 and extending from main body 64 to terminate at second end 70. In one embodiment, tab 62 includes an extension 72 at second end 70. Tabs 62 are compressible and expandable in relation to main body 64. In an expanded state, second ends 70 of tabs 62 extend a distance from main body 64. In a compressed state, which is also a biased state, tabs 62 are compressed such that second ends 70 and extensions 72 are adjacent to main body 64. When compressed, head 50 has a perimeter which is smaller or equal to first perimeter 56 of middle section 52, and when expanded, head 50 has a perimeter which is larger than hole 22. In this manner, clamp retainer 20 is insertable into hole 22 and is prevented from being removed from PCB 12 until tabs 62 are once again compressed. Accordingly, clamp retainer 20 is removably attachable to PCB 12.

When fully assembled with PCB 12, head 50 extends above front surface 24 of PCB 12, middle section 52 extends within hole 22 and bottom section 54 abuts back surface 26 of PCB 12. In one embodiment, clamp retainer 20 is injected molded plastic of approximately 6 mm outside diameter and 12 to 15 mm tall. In one embodiment, middle section 52 is configured to fit within a 3 mm hole 22. Clamp retainer 20 can be made of low cost material such as a plastic of various kinds.

FIGS. 4A and 4B illustrate exploded cross-sectional views of heat sink assembly 10. With particular reference to FIG. 4A, clamp 18 is assembled with PCB 12, heat sink 14 and clamp retainer 20. Leg 46 of clamp 18 extends through hole 22 of PCB 12 along groove 60 of clamp retainer 20. Foot 48 of clamp 18 extends through to contact back surface 26 of PCB 12. In one embodiment, foot 48 extends parallel to bottom surface 26 of PCB 12 as does contact surface 66 of end section 54 which is adjacently disposed to foot 48. Middle section 56 of clamp retainer 20 extends within hole 22 such that end section 54 is positioned along back surface 26. Head 50 extends above front surface 24 of PCB 12 and tabs 62 contact front surface 24 of PCB 12 adjacent to hole 22. In one embodiment, extensions 72 of tabs 62 extend partially into and contact the sides of hole 22. Clamp retainer 20 restricts and/or prevents lateral movement of leg 46 and prevents foot 48 from releasing from back surface 26 of PCB and re-entering hole 22.

As illustrated further in FIG. 4B, head 50 extends between leg 46, edge 44 of clamp 18 and perimeter edge 34 of heat sink 14. In one embodiment, edge 44 and leg 46 are perpendicular to front surface 24 of PCB 12. Clamp retainer 20 is configured to prevent heat sink 14 from becoming dislodged and moving across the surface of the heat spreader 28 and assist in positioning heat sink 14 on heat producing device 29 as desired. Clamp retainer 20 is unstressed by clamp 18.

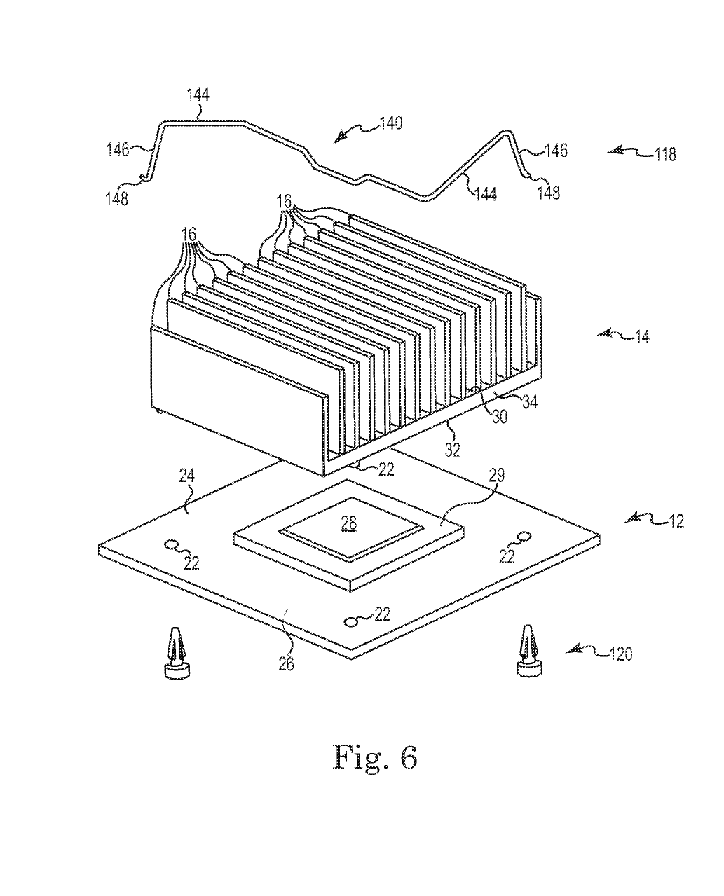

FIGS. 5 and 6 are top perspective views of one embodiment of a heat sink assembly 100. As with previous embodiments, heat sink 14 is assembled to PCB 12, heat generating device 29, and heat spreader 28. A clamp 118 secures heat sink 14 and clamp retainers 120 extend through PCB 12 to secure clamp 118. Clamp 118 is a wire spring clamp formed of a single piece of spring wire. Clamp 118 produces sufficient force to secure heat sink 14 to heat generating device 29 and PCB 12. Clamp 118 can take a multitude of different configurations, being of bent wire, and be suitable for its intended purpose. Factors which contribute to determining the size, material, and formed shape characteristics of clamp 118 include the load requirement of the thermal interface material of heat spreader 29 and the mass of heat sink 14, for example.

Clamp 118 includes a beam 140, edges 144 extending from opposing ends of beam 140, and legs 146 extending from each edge 144 opposite beam 140 and terminating at feet 148. Beam 140 is extendable between adjacent fins 16 of heat sink 14. When biased, legs 146 are urged downward into holes 22 until feet 148 are fully extended through hole 22 at back surface 26 of PCB 12. Feet 148 then resiliently abut against back surface 26. Clamp retainer 120 is inserted into hole 22 alongside leg 146. Clamp retainer 120 is inserted upward from back surface 26 to secure leg 146 within hole 22. Clamp retainer 120 is similar to clamp retainer 20, however, groove 160 is sized and shaped to accommodate the wire formed leg 146 and foot 148 of clamp 118. In one embodiment, the spring wire forming clamp 118 is 0.5 to 2 mm thick.

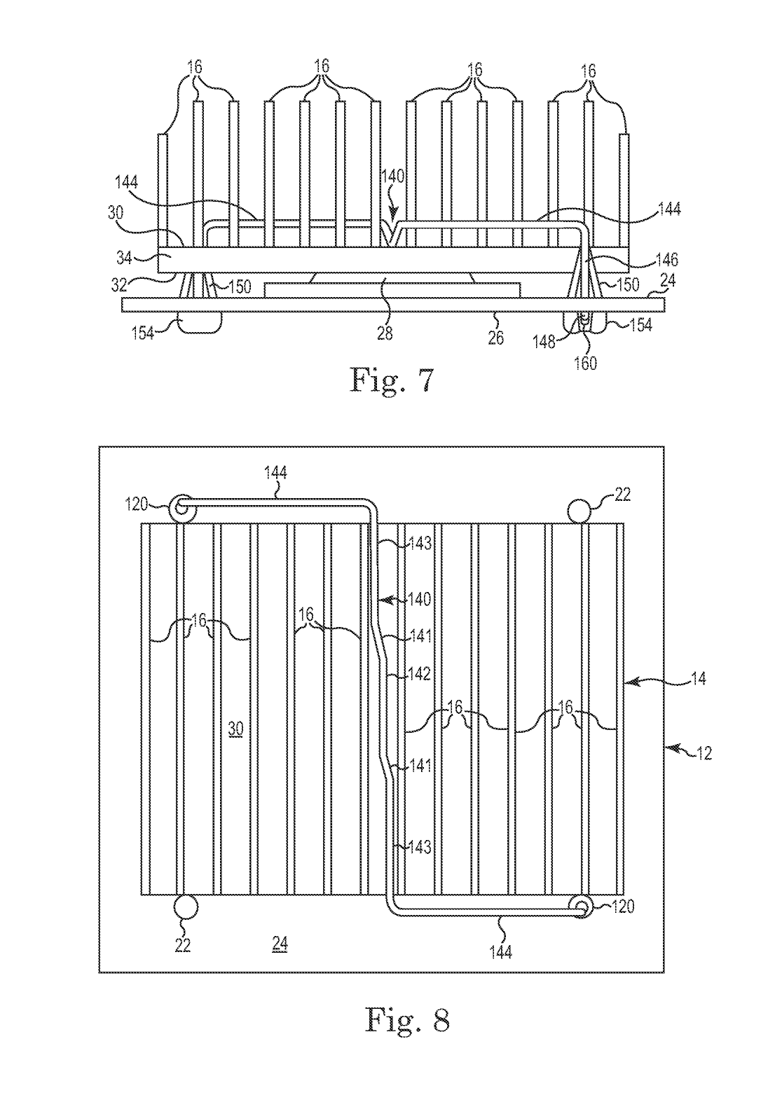

FIG. 7 is a side view of heat sink assembly 100 according to the embodiment illustrated in FIG. 5. Beam 140 extends between adjacent fins 16, forming a V-shape, and contacts a top surface 30 of heat sink 14. In one embodiment, edges 144 and lengths 142 are parallel to top surface 30 of heat sink 14. In one embodiment, beam 140 contacts and applies force to top surface 30 of heat sink 14 directly over heat spreader 28 and heat producing device 29. Beam 140 contacts heat sink 14 in a manner which prevents rocking or deformation of heat sink 14.

FIG. 8 illustrates a top view of heat sink assembly 100 according to the embodiment illustrated in FIG. 5. In one embodiment, center length 142 is depressed with respect to end lengths 143 and contacts top side 30 of heat sink 14. In one embodiment, beam 140 extends upward at bends 141 to end lengths 143 on each side of center length 142. Center length 142 is centered over heat spreader 28 and can be the same length as heat spreader 28 or slightly shorter or longer. Opposing edges 144 extends along opposing perimeter sides 34 of heat sink 14 in opposite directions from beam 140. In one embodiment, edges 144 extend parallel to perimeter edges 34 of heat sink 14 in opposite directions but do not contact perimeter edges 34. In one embodiment, a pair of clamps 118 is used in combination to extend over heat sink 14 in an X-type formation.

In one embodiment, PCB 12 includes only two holes 22 positioned diagonally opposite corners of heat sink 14 to correspond with the extension of legs 146. In another embodiment, additional holes 22 are provided and clamp retainers 120 can be inserted into holes 22 in which legs 146 are not inserted. Head 50 of clamp retainer 20 is assembled between perimeter edge 34 and edge 144 at holes 22. As with previous embodiments, clamp retainer 120 is configured to prevent heat sink 14 from becoming dislodged and moving across the surface of the heat spreader 28 and assist in positioning heat sink 14 on heat producing device 29 as desired. Clamp retainer 120 is unstressed by clamp 118.

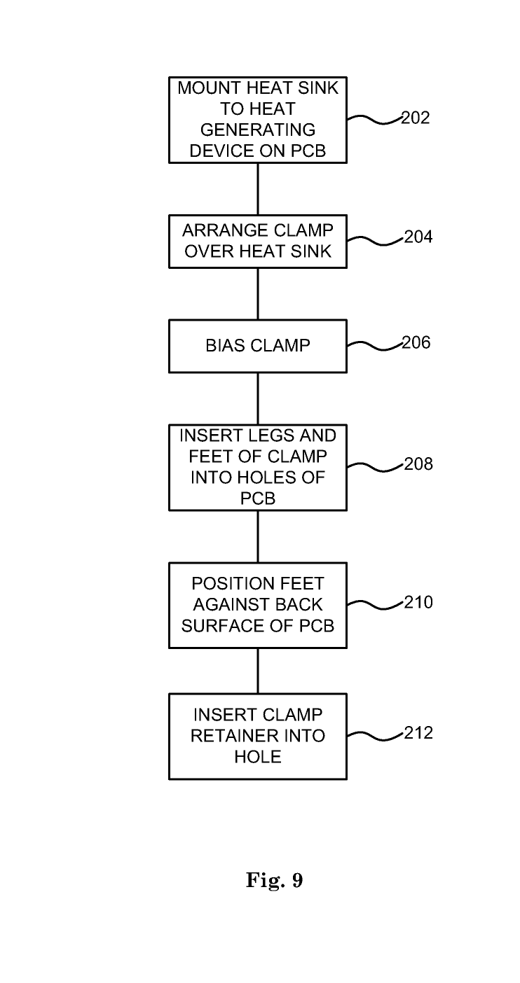

FIG. 9 illustrates one embodiment of a method of assembling a heat sink assembly. At 202, the heat sink 14 is mounted over heat generating device 29 on PCB 12. At 204, clamp 18 is arranged over heat sink 14. At 206, clamp 18, 118 is biased. At 208, legs 46, 146 and feet 48, 148 of clamp 18, 118 are inserted into holes 22 in PCB 12. At 210, feet 48, 148 are positioned against back surface 26 of PCB 12. At 212, clamp retainer 20, 120 is inserted into each hole 22 occupied by leg 46, 146. Groove 60 of clamp retainer 20, 120 receives legs 46, 146 and feet 48, 148. Tabs 62 of clamp retainer 20, 120 compress during insertion into hole 22 and expand along front surface 24 of PCB 12 when fully inserted.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A heat sink assembly, comprising:
a printed circuit board having at least two holes extending from a front surface to a back surface of the printed circuit board;
a heat sink mounted to the printed circuit board, the heat sink having a bottom side and a top side with a plurality of fins extending from the top side;
a clamp coupled to the printed circuit board, the clamp including a beam extending across the heat sink and between adjacent fins, at least two legs extending through the at least two holes of the printed circuit board, and a foot extending from each of the at least two legs contacting the back surface of the printed circuit board; and
at least two clamp retainers extending through the at least two holes adjacent to the at least two legs.

2. The heat sink assembly of claim 1, wherein the clamp retainer includes a head with compressible tabs, a middle section having a first perimeter configured to fit within the hole, and a bottom section having a second radius larger than the first radius.

3. The heat sink assembly of claim 2, wherein the at least two clamp retainers include a groove extending from the head to the bottom section.

4. The heat sink assembly of claim 2, wherein the head extends above the front surface of the printed circuit board, the middle section extends within the hole, and the bottom section abuts the bottom surface of the printed circuit board.

5. The heat sink assembly of claim 1, wherein the clamp is a stamped spring clamp.

6. The heat sink assembly of claim 5, wherein the body includes opposing edges and at least two beams perpendicular to the opposing edges configured to extend between fins of the heat sink.

7. The heat sink assembly of claim 1, wherein the feet are configured at an angle to the legs.

8. A heat sink assembly, comprising:
a printed circuit board including a heat generating device mounted to a front surface, an opposing back surface, and at least two holes extending through the printed circuit board from the front surface to the back surface;
a heat sink mounted to the front surface over the heat generating device and between the at least two holes, wherein the heat sink includes a bottom side, a top side with a plurality of fins extending from the top side, and a perimeter edge extending between the bottom side and the top side;
a clamp configured to couple the heat sink to the printed circuit board, wherein the clamp extends over the top side of the heat sink between the fins and through the at least two holes of the printed circuit board to contact the back surface; and
at least two clamp retainers extending through the at least two holes adjacent to the clamp and contacting the front surface and the back surface of the printed circuit board.

9. The heat sink assembly of claim 8, wherein the at least two clamp retainers are configured to extend adjacent to the perimeter edge of the heat sink.

10. The heat sink assembly of claim 8, wherein the at least two holes is four holes in a rectangular configuration positioned adjacent to the perimeter of the heat sink.

11. The heat sink assembly of claim 10, wherein the clamp includes four legs extending through the four holes and feet contacting the bottom side of the printed circuit board, and wherein one of the at least two clamp retainers extends through each of the four holes.

12. The heat sink assembly of claim 8, wherein the clamp is in a biased state when assembled to the printed circuit board.

13. The heat sink assembly of claim 8, wherein the clamp comprises a bent wire including a middle section configured to extend between two adjacent fins, a first section and a second end section extending from opposing ends of the middle section and in opposing directions along opposing sides of the heat sink, and legs extending from each of the first and second end sections configured to extend through the at least two holes and contact the back surface of the printed circuit board.

14. The heat sink assembly of claim 13, comprising:
a second clamp coupled to the printed circuit board to extend in opposite directions along the opposing sides of the heat sink as the clamp.

15. The heat sink assembly of claim 8, wherein the clamp comprises a stamped metal plate including a body and at least two legs, wherein the body includes at least one set of parallel beams configured to extend along opposing sides of a fin, and wherein the at least two legs extend from opposing ends of the body.

16. The heat sink assembly of claim 15, wherein the beams in an unbiased state are arcuate and in a biased state are planar.

17. A method of assembly, comprising:
mounting a heat sink having a top side including extruded fins over a heat generating device mounted to a printed circuit board;
arranging a clamp over the top side of the heat sink, the clamp including a beam, at least two legs, and at least two feet at an angle to the at least two legs, the beam arranged between two adjacent extruded fins from a first perimeter side to an opposing second perimeter side opposite the first perimeter side of the heat sink,
biasing the clamp to extend the beam across the heat sink;
inserting the at least two legs and at least two feet through holes in the printed circuit board;
positioning the feet against a back surface of the printed circuit board; and
inserting a clamp retainer into each hole occupied by a leg.

18. The method of assembly of claim 17, wherein the clamp retainer includes tabs which compress during insertion into the hole and expand along a front surface of the printed circuit board when fully inserted.

19. The method of assembly of claim 17, wherein the clamp retainer restricts lateral movement of the leg of the clamp within the hole of the printed circuit board.

20. The method of assembly of claim 17, wherein the clamp retainer prevents the feet from releasing from the back surface of the printed circuit board.
